(19) United States
(12) Patent Application Publication
(10) Pub. No.: US 2010/0307684 A1
(43) Pub. Date: Dec. 9, 2010

(54) PLASMA PROCESSING APPARATUS

(75) Inventors: Ryosaku Ota, Hyogo-ken (JP); Hikaru Adachi, Hyogo-ken (JP); Toshio Nakanishi, Hyogo-ken (JP); Atsushi Ueda, Hyogo-ken (JP); Songyun Kang, Yamanashi-ken (JP); Paul Moroz, Beverly, MA (US); Peter Ventzek, Tokyo-To (JP)

Correspondence Address: SMITH, GAMBRELL & RUSSELL, 1130 CONNECTICUT AVENUE, N.W., SUITE 1130, WASHINGTON, DC, 20036, US

(73) Assignee: Tokyo Electron Limited, Tokyo-to (JP)

(21) Appl. No.: 12/680,321

(22) PCT Filed: Sep. 26, 2008
(86) PCT No.: PCT/JP2008/067513

§ 371 Date: Aug. 27, 2010

(30) Foreign Application Priority Data
Sep. 28, 2007 (JP) 2007-254270
Sep. 28, 2007 (JP) 2007-254271

(51) Int. Cl. H01L 21/306

(52) U.S. Cl. 156/345.29

(57) ABSTRACT

A microwave plasma processing apparatus (100) of a slot antenna type includes a plane antenna plate (31) constituting a flat waveguide and a cover (34) of a conductive member. The cover (34) is provided with a stub (43) as a second waveguide for adjusting electric field-distribution in the flat waveguide. The stub (43) is provided in the cover (34) of the conductive member. In plan view, the stub (43) is arranged to overlap slots (32) constituting a slot pair arranged at the outermost circumference of the plane antenna plate (31). By appropriately arranging the stub, it is possible to control electric field-distribution in the flat waveguide thereby to generate a uniform plasma.

### TECHNICAL FIELD

The present invention relates to a plasma processing apparatus for processing a processing object with a plasma generated by introducing microwaves into a processing container by means of a plane antenna having slots.

### BACKGROUND ART

As a plasma processing apparatus for carrying out plasma processing, such as oxidation or nitridation, of a processing object such as a semiconductor wafer, an apparatus is known which generates a plasma in a processing chamber by introducing microwaves having a predetermined frequency, for example 2.45 GHz, into the processing chamber by using a slot antenna (see e.g. Japanese Patent Laid-Open Publications Nos. 11-260594 and 2001-223171). Such a microwave plasma processing apparatus is capable of forming a surface wave plasma having a high plasma density.

With reference to such a slot antenna-type plasma processing apparatus, the distribution of plasma is likely to somewhat differ even among the same apparatuses of the same specification, operating under the same conditions. Further, when processing conditions are changed in a plasma processing apparatus, a plasma in a processing chamber is likely to become unstable or uneven. To generate a stable plasma after a change in processing conditions, it is necessary to change the shape of the slots of a slot antenna, the arrangement of the slots, the shape of a microwave-transmissive plate, etc. Thus, a considerable modification of the apparatus needs to be made for every different process. In addition, especially when a large-sized substrate such as a semiconductor wafer is processed, the formation of an unstable or uneven plasma in a processing chamber may result in uneven processing in the entire surface of the substrate.

In order to distribute microwave power uniformly about the periphery of a plasma forming portion, it has been proposed to provide stubs at predetermined intervals along a coaxial line coupled to a microwave power source in an electron cyclotron resonance (ECR)-type microwave plasma processing apparatus (see e.g. Published Japanese Translation of International Patent Publication No. 2000-514595). Further, a technique has been proposed which, in a plasma processing apparatus using a high-frequency power of 100 to 1000 MHz, employs stubs arranged in the ceiling of an antenna container, in which rods are disposed radially, so that a capacitance will be formed and a resonant state will be created between the ceiling of the container and the rods (see e.g. Japanese Patent Laid-Open Publication No. 11-297494).

Neither of the plasma processing apparatuses described in the above-cited Patent Publications Nos. 2000-514595 and 11-297494 is a slot antenna-type plasma processing apparatus. Adequate studies have not been conducted on a technique for ensuring, in a slot antenna-type microwave plasma processing apparatus, the uniformity of plasma not by a change in the shape and arrangement of slots, but by using a member, such as a stub, which adjusts a microwave electromagnetic field.

### DISCLOSURE OF THE INVENTION

The present invention has been made in view of the above situation. It is therefore an object of the present invention to provide a technique which makes it possible to form a uniform electric field in a slot antenna-type microwave plasma processing apparatus by controlling the distribution of electric field in the vicinity of a slot antenna, thereby generating a uniform plasma.

In order to achieve the object, the present invention provides a plasma processing apparatus comprising: an evacuable processing container for housing a processing object; a transmissive plate hermetically mounted in a top opening of the processing container and which is transmissive to microwaves for plasma generation; a plane antenna, disposed close to or in contact with the upper surface of the transmissive plate, for introducing microwaves into the processing container, said antenna including a plate-like substrate of conductive material, having a plurality of slots that penetrate through the substrate; a conductive member covering from above the plane antenna; a first waveguide, penetrating through the conductive member, for supplying microwaves from a microwave generation source to the plane antenna; and at least one second waveguide for adjusting the distribution of electric field in the plane antenna.

The second waveguide may be partly of wholly comprised of a hollow member having a cavity and inserted into the conductive member.

Alternatively, the second waveguide may be partly or wholly comprised of an opening which penetrates through the conductive member.

Alternatively, the second waveguide may be partly or wholly comprised of a recess formed in the conductive member.

The upper end of the second waveguide may be closed.

The second waveguide may be disposed over at least one of the plurality of slots.

In a preferred embodiment, the plurality of slots are comprised of slot pairs of two slots and the slot pairs are arranged in concentric circles, and the second waveguide is disposed over at least one of the two slots of a slot pair. In this case, in a plane view, the entire area of the opening of said at least one of the two slots of the slot pair may be fully included in the area of the interior space of the second waveguide.

In a preferred embodiment, the plurality of slots are comprised of slot pairs of two slots and the slot pairs are arranged in concentric circles, and the second waveguide is disposed over the center of a radially outer one of the two slots of an outermost slot pair. In this case, in a plane view, the center of the second waveguide may position on an arc connecting the centers of radially inner slots of outermost slot pairs. Alternatively, in a plan view, the center of the second waveguide may coincide with the center of the radially inner one of the two slots of the outermost slot pair.

In a preferred embodiment, the plurality of slots are comprised of slot pairs of two slots and the slot pairs are arranged in concentric circles, and the second waveguide is disposed over the center of a radially outer one of the two slots of an outermost slot pair. In this case, in a plane view, the center of the second waveguide may position on an arc connecting the centers of radially outer slots of outermost slot pairs. Alternatively, in a plan view, the center of the second waveguide may coincide with the center of the radially outer one of the two slots of the outermost slot pair.

Preferably, a plurality of second waveguides are provided as said at least one second waveguide, and the number of the second waveguides is within the range of 2 to 4.

Preferably, at least two of the plurality of second waveguides are arranged radially symmetrically with respect to the center of the plane antenna.

The plurality of second waveguides may each be disposed over a line extending radially outward from the center of the plane antenna and connecting some slots of said plurality of slots.

The plasma processing apparatus may further comprise a retardation plate, disposed on the plane antenna, for adjusting the wavelength of microwaves to be supplied to the plane antenna.

According to the present invention, in the plasma processing apparatus provided with the plane antenna having a plurality of slots, the second waveguide(s) is provided in the conductive member (cover) disposed over the plane antenna such that it covers the plane antenna. The provision of the second waveguide(s) can adjust and equalize the distribution of electric field in a flat waveguide constituted by the plane antenna and the conductive member. Consequently, the coefficient of reflection (reflected waves) of microwaves to the first waveguide can be reduced and the efficiency of microwave absorption in a plasma generated in the processing container can be enhanced. Thus, loss of microwave power can be reduced and the effective power efficiency can be enhanced. In addition, a plasma can be generated stably in the processing container and a uniform plasma distribution can be achieved. This enables uniform processing in the entire surface of a processing object even when the processing object is a large-sized substrate.

### BRIEF DESCRIPTION OF THE DRAWINGS

FIG. 1 is a schematic cross-sectional view showing an exemplary plasma processing apparatus according to an embodiment of the present invention;

FIG. 2 is a diagram showing the structure of a plane antenna plate for use in the plasma processing apparatus of FIG. 1,

FIG. 3 is a perspective view illustrating the construction of a top main portion of the plasma processing apparatus of FIG. 1;

FIG. 4 is a block diagram illustrating the schematic construction of the control system of the plasma processing apparatus of FIG. 1;

FIG. 5 is a cross-sectional view of an upper main portion of the plasma processing apparatus of FIG. 1, illustrating the construction of a stub;

FIG. 6 is a cross-sectional view of an upper main portion of the plasma processing apparatus, illustrating the construction of another stub;

FIG. 7 is a cross-sectional view of an upper main portion of the plasma processing apparatus, illustrating the construction of yet another stub;

FIG. 8 is a cross-sectional view of an upper main portion of the plasma processing apparatus, illustrating the construction of yet another stub;

FIG. 9 is a cross-sectional view of an upper main portion of the plasma processing apparatus, illustrating the construction of yet another stub;

FIG. 10 is a diagram illustrating an example of the position of a stub with respect to slots;

FIG. 11 is a diagram illustrating another example of the position of a stub with respect to slots;

FIG. 12 is a diagram illustrating yet another example of the position of a stub with respect to slots;

FIG. 13 is a diagram illustrating the balance of microwave powers in a simulation;

FIG. 14 is a diagram illustrating an example of the number of stubs arranged with respect to a plane antenna plate;

FIG. 15 is a diagram illustrating another example of the number of stubs arranged with respect to the plane antenna plate;

FIG. 16 is a diagram illustrating yet another example of the number of stubs arranged with respect to the plane antenna plate;

FIG. 17 is a diagram illustrating an arrangement of stubs with respect to the plane antenna plate;

FIG. 18 is a diagram illustrating another arrangement of stubs with respect to the plane antenna plate;

FIG. 19 is a diagram illustrating yet another arrangement of stubs with respect to the plane antenna plate;

FIG. 20 is a diagram illustrating the arrangement positions and the number of stubs in a simulation;

FIG. 21 is a diagram illustrating the arrangement positions and the number of stubs in a simulation;

FIG. 22 is a diagram illustrating the arrangement positions and the number of stubs in a simulation;

FIG. 23 is a diagram illustrating the arrangement positions and the number of stubs in a simulation;

FIG. 24 is a diagram illustrating the arrangement positions and the number of stubs in a simulation;

FIG. 25 is a diagram illustrating the arrangement positions and the number of stubs in a simulation;

FIG. 26 is a diagram illustrating the arrangement positions and the number of stubs in a simulation;

FIG. 27 is a diagram illustrating a variation of the position of a stub with respect to slots;

FIG. 28 is a schematic cross-sectional view showing the construction of a plasma processing apparatus used in an experiment;

FIG. 29 is a plan view showing the positional relationship between stubs and slots in the plasma processing apparatus used in the experiment;]

FIG. 30 is a graph showing the relationship between the height of a stub and the electric field intensity in the ceiling plate portion;

FIG. 31 is a diagram showing the results of a first experiment; and

FIG. 32 is a diagram showing the results of a second experiment.

### BEST MODE FOR CARRYING OUT THE INVENTION

### First Embodiment

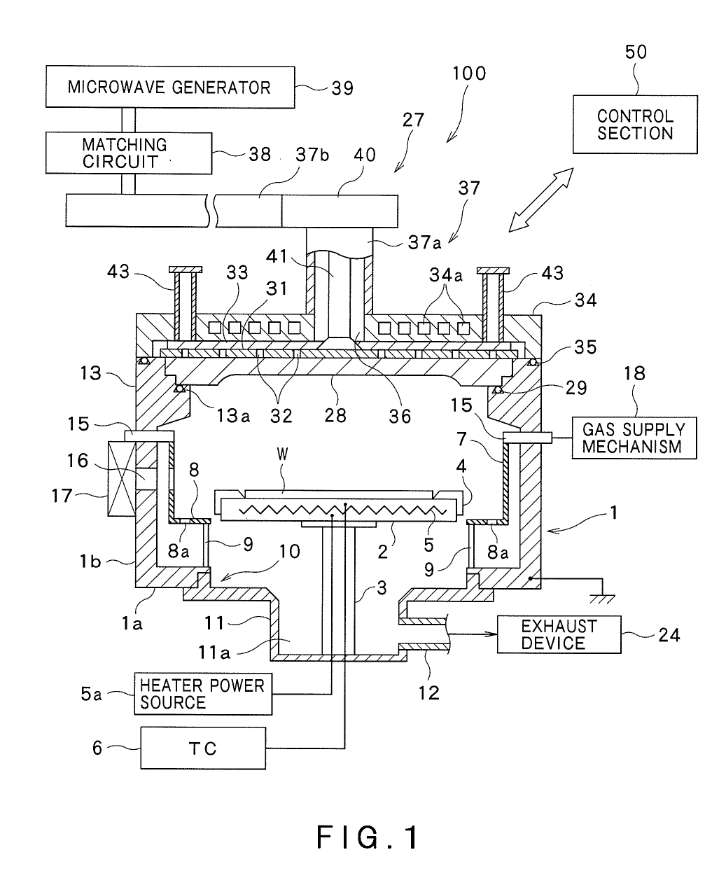

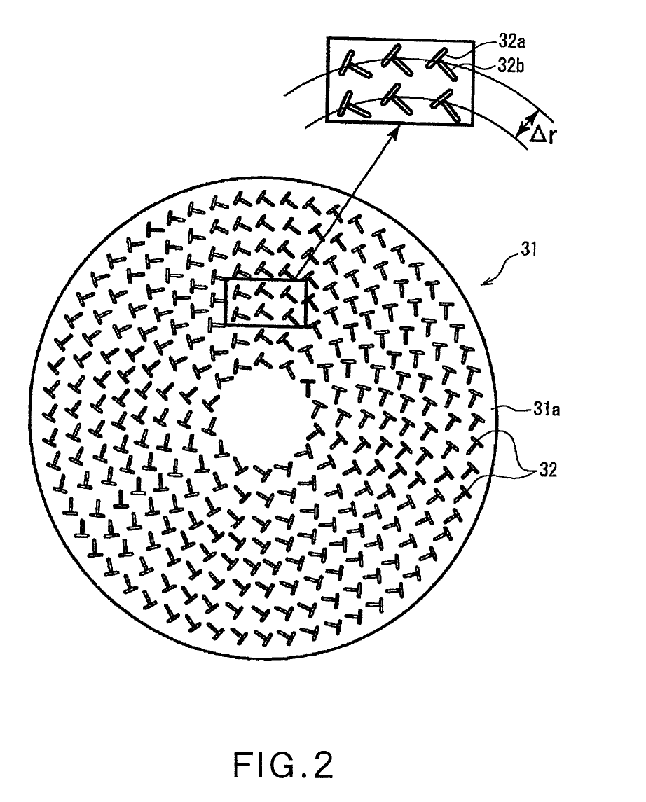

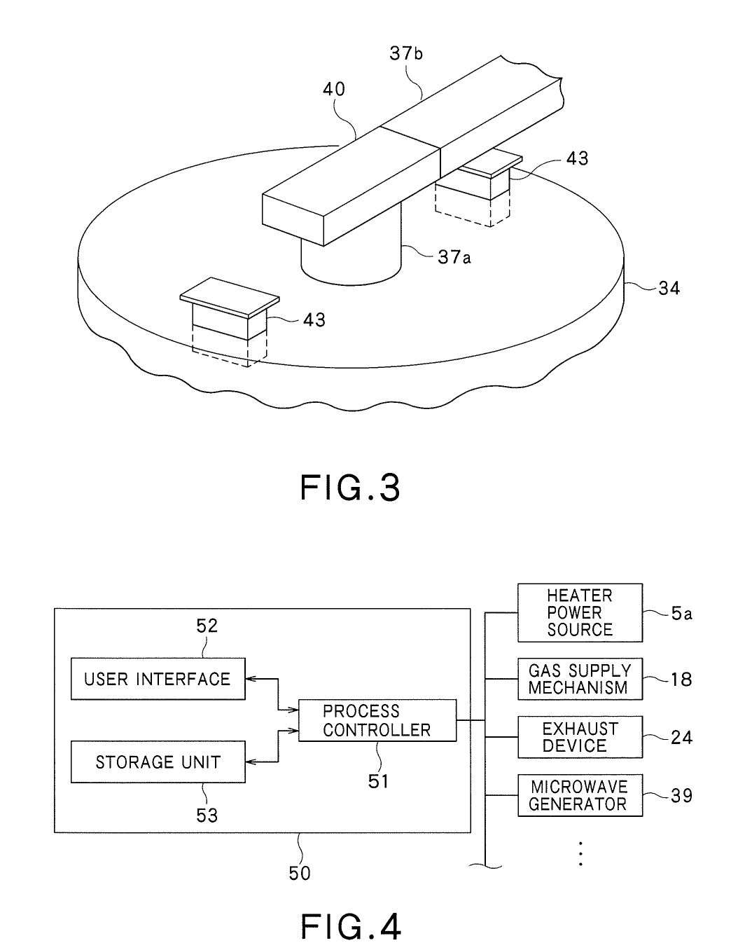

Preferred embodiments of the present invention will now be described in detail with reference to the drawings. FIG. 1 is a cross-sectional view schematically showing the construction of a plasma processing apparatus 100 according to a first embodiment of the present invention. FIG. 2 is a plan view showing the plane antenna of the plasma processing apparatus 100 of FIG. 1. FIG. 3 is a perspective view illustrating the schematic construction of the top portion of the plasma processing apparatus 100 of FIG. 1. FIG. 4 is a diagram illustrating the schematic construction of the control system of the plasma processing apparatus 100 of FIG. 1.

The plasma processing apparatus 100 is constructed as a plasma processing apparatus capable of generating a high-density, low-electron temperature, microwave-excited plasma by introducing microwaves into a processing chamber by means of a plane antenna having a plurality of slot-like holes, in particular an RLSA (radial line slot antenna). The plasma processing apparatus 100 can perform processing with a plasma having a plasma density of 1×10¹⁰ to 5×10¹²/cm³ and a low electron temperature of 0.7 to 2 eV. The plasma processing apparatus 100 can therefore be advantageously used in the manufacturing of a variety of semiconductor devices.

The plasma processing apparatus 100 comprises the following main components: an airtight chamber (processing chamber) 1; a gas supply mechanism 18 for supplying a gas into the chamber 1; an exhaust device 24 as an exhaust mechanism for evacuating and depressurizing the chamber 1; a microwave introduction mechanism 27, provided above the chamber 1, for introducing microwaves into the chamber 1; and a control section 50 as a control means for controlling these components of the plasma processing apparatus 100. The gas supply mechanism 18, the evacuation device 24 and the microwave introduction mechanism 27 constitute a plasma generation means for generating a plasma in the chamber 1.

The chamber 1 is formed by a grounded, generally-cylindrical container. The chamber 1 may be formed by a container of a rectangular cylinder shape. The chamber 1 has a bottom wall 1a and a side wall 1b, e.g. made of aluminum.

In the chamber 1, a stage 2 is provided to horizontally support a silicon wafer (hereinafter referred to simply as “wafer”) W as a processing object. The stage 2 is made of a material having high thermal conductivity, for example, a ceramic material such as AlN. The stage 2 is supported by a cylindrical support member 3 extending upwardly from the center of the bottom of an exhaust chamber 11. The support member 3 is made of e.g. a ceramic material such as AlN.

The stage 2 is provided with a cover ring 4 for covering a peripheral portion of the stage 2 and guiding the wafer W. The cover ring 4 is an annular member made of e.g. quartz, AlN, Al₂O₃ or SiN.

A resistance heating-type heater 5 as a temperature adjustment mechanism is embedded in the stage 2. The heater 5, when powered from a heater power source 5a, heats the stage 2 and, by the heat, uniformly heats the wafer W as a processing substrate.

The stage 2 is provided with a thermocouple (TC) 6. The heating temperature of the wafer W can be controlled e.g. in the range of room temperature to 900° C. by measuring the temperature with the thermocouple 6.

The stage 2 has wafer support pins (not shown) for raising and lowering the wafer W while supporting it. The wafer support pins are each projectable and retractable with respect to the surface of the stage 2.

A cylindrical quarts liner 7 is provided on the inner periphery of the chamber 1. Further, an annular quartz baffle plate 8, having a large number of exhaust holes 8a for uniformly evacuating the chamber 1, is provided around the periphery of the stage 2. The baffle plate 8 is supported on support posts 9.

A circular opening 10 is formed generally centrally in the bottom wall 1a of the chamber 1. The bottom wall 1a is provided with a downwardly-projecting exhaust chamber 11 which communicates with the opening 10. An exhaust pipe 12 is connected to the exhaust chamber 11, and the exhaust chamber 11 is connected via the exhaust pipe 12 to the exhaust device 24.

At the upper end of the chamber 1 is disposed a plate 13, having a large opening, which functions as a lid capable of opening the interior space of the chamber. An inwardly-projecting annular support portion 13a is formed in the inner periphery of the plate 13.

The side wall 1b of the chamber 1 is provided with an annular gas introduction section 15. The gas introduction section 15 is connected to a gas supply mechanism 18 for supplying an oxygen-containing gas and a plasma excitation gas. It is also possible to construct the gas introduction section 15 in the shape of a nozzle or a shower head.

The side wall 1b of the chamber 1 is also provided with a transfer port 16 for transferring the wafer W between the plasma processing apparatus 100 and an adjacent transfer chamber (not shown), and a gate valve 17 for opening and closing the transfer port 16.

The gas supply mechanism 18 includes gas supply sources (not shown) for supplying gases, such as a rare gas for plasma generation, such as Ar, Kr, Xe or He gas; a processing gas, such as oxygen gas for oxidation processing or nitrogen gas for nitridation processing; a raw material gas for CVD processing; a purge gas for replacement of the interior atmosphere of the chamber 1, such as N₂ or Ar gas; a cleaning gas for cleaning of the interior of the chamber 1, such as ClF₃ or NF₃ gas. Each gas supply source is provided with a not-shown mass flow controller and a not-shown on-off valve so that switching of gases to be supplied and control of gas flow rate can be performed.

The exhaust device 24 as an exhaust mechanism includes a high-speed vacuum pump, such as a turbo-molecular pump. As described above, the exhaust device 24 is connected via the exhaust pipe 12 to the exhaust chamber 11 of the chamber 1. By the actuation of the exhaust device 24, the gas in the chamber 1 uniformly flows into the space 11a of the exhaust chamber 11, and is discharged from the space 11a through the exhaust pipe 12 to the outside. The chamber 1 can thus be quickly depressurized e.g. into 0.133 Pa.

The construction of the microwave introduction mechanism 27 will now be described. The microwave introduction mechanism 27 mainly comprises a transmissive plate 28, a plane antenna plate 31, a retardation plate 33, a cover 34 comprised of a conductive member, a waveguide 37 as a first waveguide, a matching circuit 38 and a microwave generator 39. The plane antenna plate 31 and the cover 34 constitute a flat waveguide. In the plasma processing apparatus 100 of this embodiment, the microwave introduction mechanism 27 is provided with at least one (e.g. two as shown in FIGS. 1 and 3) stub 43 as a second waveguide for adjusting the distribution of electric field in the flat waveguide.

The transmissive plate 28, which is transmissive to microwaves, is supported on the inwardly-projecting support portion 13a of the plate 13. The transmissive plate 28 is composed of a dielectric material, for example, a ceramic material such as quartz, Al₂O₃, AlN, etc. The transmissive plate 28 and the support portion 13a are hermetically sealed with a seal member 29, so that the chamber 1 is kept hermetic.

The plane antenna plate 31 is provided over the transmissive plate 28 such that it faces the stage 2. The plane antenna plate 31 has a disk-like shape. The shape of the plane antenna plate 31 is not limited to a disk-like shape: for example, the antenna may be of a square plate-like shape. The plane antenna 13 is locked into the upper end of the plate 13.

As shown in FIG. 2, the plane antenna plate 31 includes a substrate 31a comprised of e.g. a copper plate or an aluminum plate, whose surface is plated with gold or silver. A large number of slots 32, penetrating through the substrate 31a, are formed in the substrate 31a. The slots 32 are arranged in a predetermined pattern. Each slot 32 is a narrow opening. In the embodiment illustrated in FIG. 2, the slots 32 are arranged in concentric circles and in a large number of slot pairs. The slot pairs are arranged in concentric circles. Each slot pair is comprised of adjacent two slots 32 which differ in orientation. In particular, each slot pair is comprised of a slot 32a whose longitudinal direction makes a first angle with the radial direction of the substrate 31a, and a slot 32b whose longitudinal direction makes a second angle with the radial direction of the substrate 31a. A plurality of slot pairs line up along a circle centered at the center of the substrate 31a. Preferably, a plurality of slot pairs line up along each of a plurality of concentric circles having different radiuses, as shown in FIG. 2. In FIG. 2, the radial spacing between radially adjacent slot pairs, i.e. the spacing between adjacent concentric circles, is denoted by Δr.

The arrangement, the number, the arrangement spacings, the arrangement angles, etc. of the slots 32 of the plane antenna plate 31, shown in FIG. 2, are illustrated merely by way of example. The length of the slots 32 and the arrangement spacings can be determined depending on the wavelength (λg) of microwaves. For example, the slots 32 are preferably arranged with a circumferential spacing in the range of λg/4 to λg. The slots 32 may have other shapes, such as a circular shape and an arch shape. The arrangement configuration of the slots 32 is not limited to concentric circles: the slots 32 may be arranged e.g. in a spiral or radial configuration. It is also possible to arrange slot groups, each comprised of three of more slots, in a predetermined pattern. In the case where a substrate for a flat panel display, such as a liquid crystal display or an organic EL display, is to be processed, it is possible to arrange slots in a linear or square spiral configuration.

The retardation plate 33, made of a material having a higher dielectric constant than vacuum, is provided between the plane antenna plate 31 and the cover 34 which together constitute the flat waveguide. The retardation plate 33 is disposed such that it covers the plane antenna plate 31. Examples of the material for the retardation plate 33 include quartz, a polytetrafluoroethylene resin and a polyimide resin. The retardation plate 33 is employed in consideration of the fact that the wavelength of microwaves becomes longer in vacuum. The retardation plate 33 functions to shorten the wavelength of microwaves, thereby adjusting a plasma.

The plane antenna plate 31 and the transmissive plate 28 may be in contact with or spaced apart from each other, though preferably in contact with each other. The retardation plate 33 and the plane antenna plate 31 may be in contact with or spaced apart from each other, though preferably in contact with each other.

The cover 34 which, together with the plane antenna pate 31, forms the flat waveguide is provided over the chamber 1 such that it covers the plane antenna plate 31 and the retardation plate 33. The cover 34 is formed of a metal material such as aluminum or stainless steel. The upper end of the plate 13 and the cover 34 are sealed with a seal member 35, such as a spiral shield ring having electrical conductivity, so as to prevent leakage of microwaves to the outside. A cooling water flow passage 34a is formed in the cover 34. The cover 34, the retardation plate 33, the plane antenna plate 31 and the transmissive plate 28 can be cooled by passing cooling water through the cooling water flow passage 34a. The cooling mechanism can prevent the cover 34, the retardation plate 33, the plane antenna plate 31, the transmissive plate 28 and the plate 13 from being deformed or broken by the heat of plasma. The cover 34 is grounded.

An opening 36 is formed in the center of the upper wall (ceiling portion) of the cover 34, and the lower end of the waveguide 37 is connected to the opening 36. The other end of the waveguide 37 is connected via the matching circuit 38 to the microwave generator 39.

The waveguide 37 is comprised of a coaxial waveguide 37a having a circular cross-section and extending upward from the opening 36 of the cover 34, and a horizontally-extending rectangular waveguide 37b connected via a mode converter 40 to the upper end of the coaxial waveguide 37a. The mode converter 40 functions to convert microwaves, propagating in TE mode through the rectangular waveguide 37b, into TEM mode microwaves.

An inner conductor 41 extends centrally in the coaxial waveguide 37a. The inner conductor 41, at its lower end, is connected and secured to the center of the plane antenna plate 31. With such construction, microwaves are propagated through the inner conductor 41 of the coaxial waveguide 37a to the plane antenna plate 31, constituting the flat waveguide, radially, efficiently and uniformly.

The stub 43 is a rectangular waveguide comprised of a hollow tubular member having a rectangular cross-section, as shown in FIG. 3. The stub 43 is formed of a metal material, such as aluminum or stainless steel. The stub 43 is disposed vertically in a peripheral portion of the cover 34. The lower portion of the stub 43 is inserted into the cover 34, penetrating through the cover 34. The upper portion of the stub 43 projects from the upper surface of the cover 34. The shape of the stub 43, the number of stubs 43, the arrangement of stubs 43, etc. in the plasma processing apparatus 100 of this embodiment will be described in detail later.

With the microwave introduction mechanism 27 thus constructed, microwaves generated in the microwave generator 39 are propagated through the waveguide 37 to the plane antenna plate 31, and introduced through the slots 32 and the transmissive plate 28 into the chamber 1. An exemplary microwave frequency which is preferably used is 2.45 GHz. Other frequencies such as 8.35 GHz and 1.98 GHz can also be used.

The components of the plasma processing apparatus 100 are each connected to and controlled by the control section 50. As shown in FIG. 4, the control section 50 includes a process controller 51 provided with a CPU, and a user interface 52 and a storage unit 53, both connected to the process controller 51. The process controller 51 is a control means which is connected to and comprehensively controls those components of the plasma processing apparatus 100 which are related to process conditions, such as temperature, gas flow rate, pressure, microwave power, etc. (heater power source 5a, gas supply mechanism 18, exhaust device 24, microwave generator 39, etc.).

The user interface 52 includes a keyboard for a process manager to perform a command input operation, etc. in order to manage the plasma processing apparatus 100, a display which visualizes and displays the operating situation of the plasma processing apparatus 100, etc. In the storage unit 53 are stored a control program (software) for executing, under control of the process controller 51, various processings to be carried out in the plasma processing apparatus 100, and a recipe in which data on processing conditions, etc. is recorded.

A desired processing is carried out in the chamber 1 of the plasma processing apparatus 100 under the control of the process controller 51 by calling up an arbitrary recipe from the storage unit 53 and causing the process controller 51 to execute the recipe, e.g. through the operation of the user interface 52 performed as necessary. With reference to the process control program and the recipe of processing condition data, etc., it is possible to use those stored in a computer-readable storage medium, such as CD-ROM, hard disk, flexible disk, flash memory, DVD, etc. or to transmit them from another device e.g. via a dedicated line as needed, and use them online.

The plasma processing apparatus 100 thus constructed enables plasma processing to be carried out at a low temperature of not more than 800° C., particularly from room temperature to 500° C., without damage to a base film, etc. Further, the plasma processing apparatus 100 is excellent in the uniformity of plasma, and can therefore achieve uniform processing.

An exemplary plasma processing process, carried out by using the plasma processing apparatus 100, will now be described taking, by way of example, a case in which a wafer surface is subjected to plasma oxidation processing using an oxygen-containing gas as a processing gas. First, a command to carry out plasma oxidation processing in the plasma processing apparatus 100 is inputted e.g. through the user interface 52. Upon receipt of the command, the process controller 51 reads out a recipe stored in the storage unit 53. The process controller 51 then sends out control signals to end devices, such as the gas supply mechanism 18, the exhaust device 24, the microwave generator 39, the heater power source 5a, etc. so that plasma oxidation processing will be carried out under conditions prescribed in the recipe.

The gate valve is opened, and a wafer W is carried through the transfer port into the chamber 1 and placed on the stage 2. Next, while evacuating and depressurizing the chamber 1, an inert gas and an oxygen-containing gas are supplied from the gas supply mechanism 18 and introduced through the gas introduction section 15 into the chamber 1 respectively at a predetermined flow rate. The pressure in the chamber 1 is adjusted to a predetermined pressure by adjusting the amount of exhaust gas and the amounts of the gases supplied.

Next, the power of the microwave generator 39 is turned on to generate microwaves. The microwaves generated, having a predetermined frequency, for example 2.45 GHz, are introduced via the matching circuit 38 into the rectangular waveguide 37b. The microwaves introduced into the rectangular waveguide 37b pass through the coaxial waveguide 37a, and are supplied to the plane antenna plate 31 constituting the flat waveguide. The microwaves propagate in TE mode in the rectangular waveguide 37b. The TE mode microwaves are converted into TEM mode microwaves by the mode converter 40, and the TEM mode microwaves are propagated in the coaxial waveguide 37a toward the plane antenna plate 31. The microwaves are then radiated from the slots 32 which penetrate through the plane antenna plate 31, and introduced through the transmissive plate 28 into the chamber 1 (into the space over the wafer W). The microwave power is preferably in the range of 0.41 to 4.19 W/cm² in terms of the microwave power density per unit area (cm²) of the transmissive plate 28. Such a microwave power as to meet this requirement may be selected, e.g. within the range of 500 to 5000 W, in accordance with the purpose.

By the microwaves radiated from the plane antenna plate into the chamber 1 via the transmissive plate 28, an electromagnetic field is formed in the chamber 1, and the inert gas and the oxygen-containing gas turn into a plasma. Because the microwaves are radiated from the large number of slots 32 of the plane antenna plate 31, the microwave-excited plasma has a high density of about 1×10¹⁰ to 5×10¹²/cm³ and, in the vicinity of the wafer W, has a low electron temperature of not more than about 1.5 eV. The microwave-excited high-density plasma thus formed causes little damage, e.g. by ions, to a base film. By the action of active species, such as radicals and ions, in the plasma, the silicon surface of the wafer W is oxidized to form a silicon oxide (SiO₂) film.

When a control signal to terminate the plasma processing is sent out from the process controller 51, the power of the microwave generator 39 is turned off to terminate the plasma oxidation processing. Next, the supply of the processing gases form the gas supply mechanism 18 is stopped to evacuate the chamber 1. The wafer W is carried out of the chamber 1, whereby the plasma processing for the one wafer W is completed.

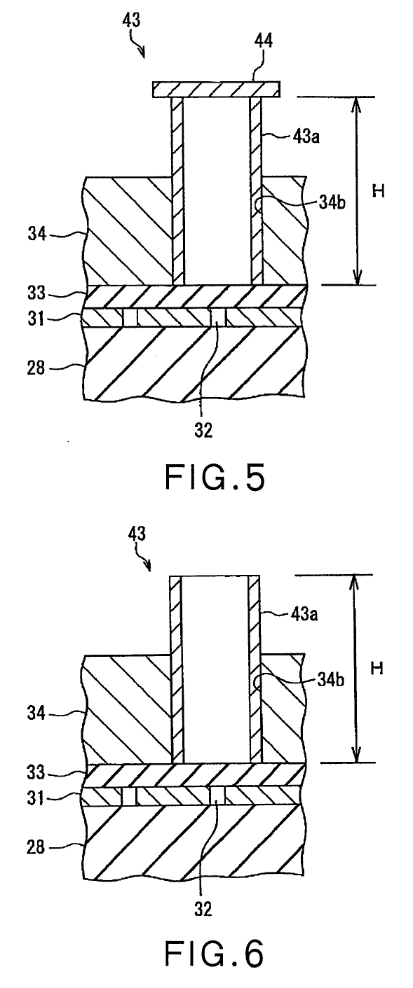

A description will now be given of the detailed construction of the stub 43 in the plasma processing apparatus 100 of this embodiment. As shown in FIG. 5, in this embodiment a hollow tubular member 43a having a rectangular cross-section, constituting the stub 43, is inserted in the lower portion into an opening 34b provided in a peripheral portion of the cover 34. The hollow tubular member 43a, having the shape of a hollow block, penetrates through the cover 34 and reaches to the upper surface of the retardation plate 33. The lower end of the hollow tubular member 43 may be in contact with or spaced apart from the retardation plate 33.

Though the upper portion of the stub 43 projects from the upper surface of the cove 34 in FIG. 5, it is also possible not to project it. The height H of the stub 43 (i.e. the length of waveguide) can be set at an appropriate value not more than the in-tube wavelength λg (=154 mm) of microwaves that propagate in the stub 43, such as λg/4 (38.5 mm), λg/2 (77 mm), 3λg/4 (115.5 mm), etc. so that a standing microwave will be generated in the stub 43. The cross-sectional area of the stub 43 can be set depending on the wavelength λg of microwaves that propagate in the stub 43.

The top of the stub 43 may be closed by a lid 44 as shown in FIG. 5, or open as shown in FIG. 6. In order to enhance the rate of absorption of microwaves in plasma and reduce reflection of microwaves to the waveguide 37, it is preferred to close the top of the stub 43 as shown in FIG. 5. In the case where the top of the stub 43 is closed, besides the mounting of the lid 44 which is a separate part from the stub 43, it is possible to use a stub 43 having an integrally-formed top portion.

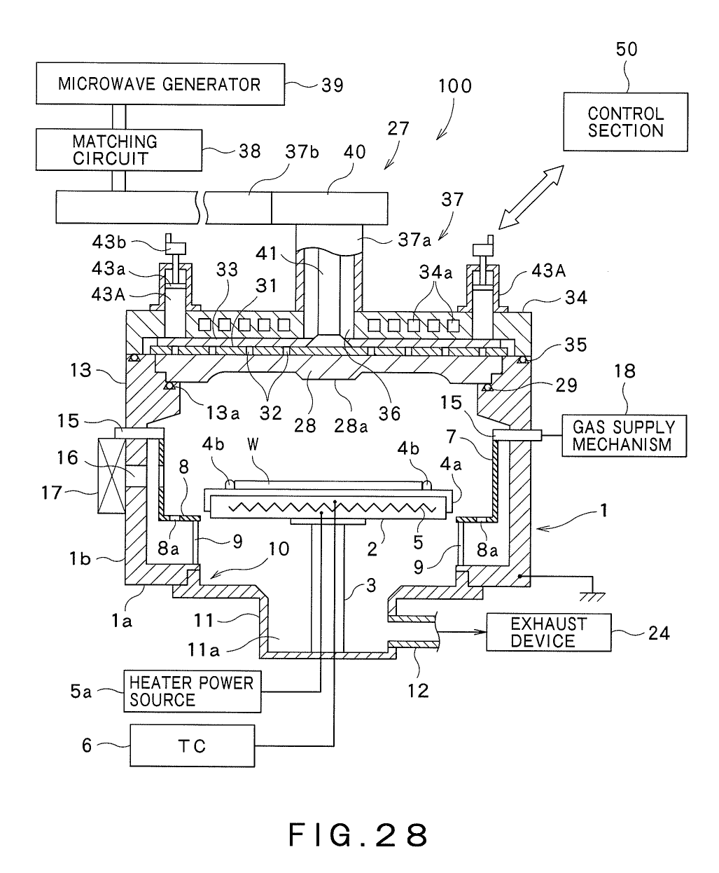

In the case where the top of the stub 43 is closed, it is also possible to provide a movable lid (movable body) instead of the lid 44 shown in FIG. 5 (see FIG. 28). The use of a movable lid can arbitrarily change the effective tube length of the stub 43. Thus, by adjusting the height of the stub, the electric field intensity in the transmissive plate 28 can be easily controlled. The use of a movable lid is therefore advantageous from the view point of enhancing the uniformity of plasma and enhancing the uniformity of processing in a wafer surface. Any mechanism may be employed to move a lid vertically. For example, a screw mechanism (see FIG. 28) capable of vertically moving and positioning a lid can be employed.

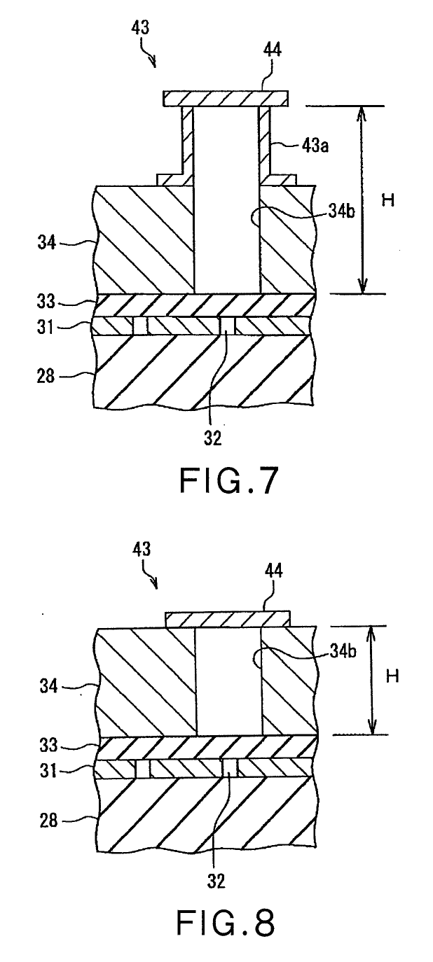

FIGS. 7 through 9 illustrate stubs 43 having different constructions. FIG. 7 illustrates a stub 43 whose upper portion is constituted by a hollow tubular member 43a having a rectangular cross-section and whose lower portion is constituted by a rectangular opening 34b formed in the cover 34. The hollow tubular member 43a is secured to the upper surface of the cover 34 by any not-shown fixing means, such as a screw. In the stub 43 shown in FIG. 7, the hollow portion of the hollow tubular member 43a and the opening 34b of the cover 34 are aligned and form a continuous vertical waveguide. The provision of the lid 44 is optional also in the stub 43 shown in FIG. 7.

FIG. 8 illustrates a stub 43 which is constituted by a rectangular opening 34b formed in the cover 34. In the stub 43 shown in FIG. 8, a vertical waveguide is formed solely by the opening 34b of the cover 34. Accordingly, the height H of the stub 43 is identical to the thickness of the cover 34. The provision of the lid 44 is optional also in the stub 43 shown in FIG. 8.

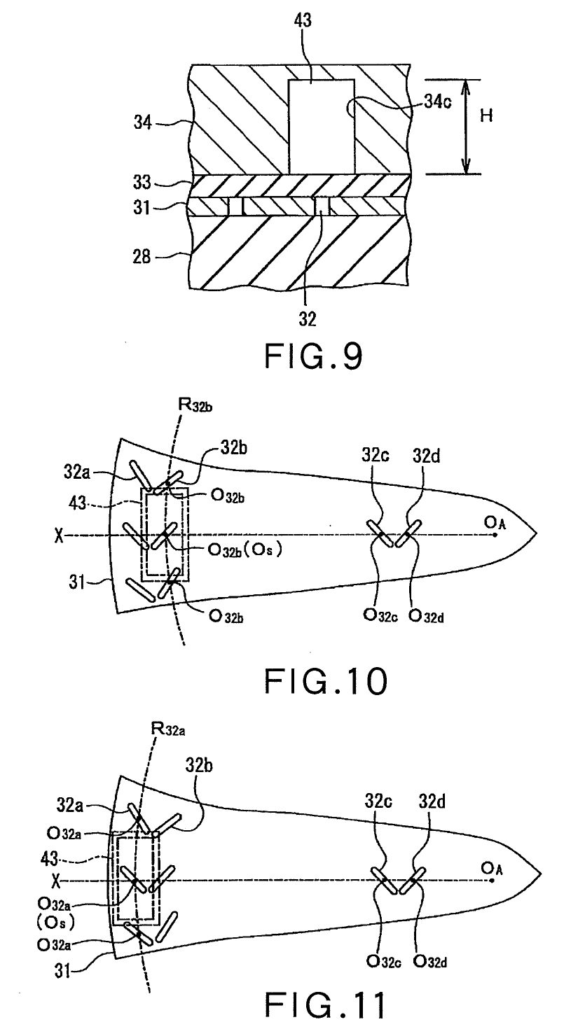

FIG. 9 illustrates a stub 43 which is constituted by a recess 34c formed in the lower surface of the cover 34. The recess 34c opens onto the retardation plate 33 disposed under the cover 34. In the stub 43 shown in FIG. 9, a vertical waveguide is formed solely by the recess 34c of the cover 34. Accordingly, the height H of the stub 43 is smaller than the thickness of the cover 34.

In the plasma processing apparatus 100 of this embodiment, the stub 43 is provided above a peripheral portion of the plane antenna plate 31 in order to generate a plasma uniformly in the chamber 1 and ensure the uniformity of processing over the central and peripheral areas of a wafer W. As described above, microwaves generated in the microwave generator 39 are supplied through the coaxial waveguide 37a to the central portion of the plane antenna plate 31, and propagate radially through the waveguide (flat waveguide) constituted by the plane antenna plate 31 and the cover 34. The longer the distance microwaves travel through the flat waveguide is, the more reflected waves are likely to be generated and a standing wave attenuates. Thus, the electric field, generate by microwaves in the flat waveguide, tends to be strong at the center of the plane antenna plate 31 at which microwaves are introduced from the lower end of the coaxial waveguide 37a into the flat waveguide, and weak in the peripheral area of the plane antenna plate 31. The electric field distribution is thus likely to be uneven over the plane antenna plate 31. Such uneven electric field distribution leads to larger coefficient of reflection to the waveguide and lower efficiency of absorption of microwaves in plasma. Therefore, the effective power of microwaves introduced into the chamber 1 decreases and the power loss increases. This will result in the generation of an uneven plasma in the chamber 1. This problem is particularly marked when the chamber 1 is a large-sized one for processing of a large-diameter wafer W: the density of plasma will be low in the vicinity of the side wall 1b of the chamber 1, making it difficult to carry out uniform processing in the entire surface of the wafer W.

In view of the above, in order to efficiently supply microwaves into the chamber 1 and generate a uniform plasma, it is preferred to dispose the stub 43 above a peripheral portion (i.e. a portion in the vicinity of the edge) of the plane antenna plate 31 to equalize the distribution of electric field over the plane antenna plate 31. When the stub 43 is disposed over a slot 32 formed in a peripheral portion of the plane antenna plate 31, microwaves are more easily introduced into the stub 43 as compared to the case where the stub 43 is disposed otherwise. By allowing uneven microwaves (reflected waves) to be absorbed in the stub 43, it becomes possible to produce a uniform electric field intensity distribution over the plane antenna plate 31.

In this embodiment, the stub 43 is preferably disposed such that in a plan view, the hollow portion of the hollow tubular stub 43 overlaps with the opening of a slot 32 formed in a peripheral portion of the plane antenna plate 31. More preferably, the stub 43 is disposed such that the hollow portion of the stub 43 positions over the center of the opening plane of a slot 32 (hereinafter referred to simply as “center of slot 32”) formed in a peripheral portion of the plane antenna plate 31. Further, the center of the opening plane of the stub 43 (hereinafter referred to simply as “center of stub 43”) preferably positions over an arc circumferentially connecting the centers of slots 32 formed in a peripheral portion of the plane antenna plate 31. More preferably, the stub 43 is disposed such that in a plan view, the center of the stub 43 coincides with the center of a slot 32 formed in a peripheral portion of the plane antenna plate 31. Further, it is desirable that the stub 43 be disposed such that in a plan view, the hollow portion of the stub 43 overlaps with the entire opening of a slot 32 (i.e. in a plan view, the entire slot 32 is fully included in the hollow portion of the stub 43).

Preferred arrangement positions of the stub 43 in the radial direction of the plane antenna plate 31 will now be described with reference to FIGS. 10 through 12. FIGS. 10 through 12 are diagrams illustrating the arrangement of the stub 43 with respect to the positions of slot pairs (slots 32a and slots 32b) arranged outermost in the plane antenna plate 31. In these Figures, the stub 43 is shown by the broken lines. FIG. 10 illustrates an embodiment in which the stub 43 is disposed such that the center O_{S} of the stub 43 positions over an arc R_{32b} connecting the centers O_{32b} of the inner slots 32b of slot pairs arranged outermost in a peripheral portion of the plane antenna plate 31. In FIG. 10, the stub 43 is also disposed such that in a plan view, the center O_{S} of the stub 43 coincides with the center O_{32b} of a slot 32b.

FIG. 11 illustrates an embodiment in which the stub 43 is disposed such that the center O_{S} of the stub 43 positions over an arc R₃₂ₐ connecting the centers O₃₂ₐ of the outer slots 32a of slot pairs arranged outermost in a peripheral portion of the plane antenna plate 31. In FIG. 11, the stub 43 is also disposed such that in a plan view, the center O_{S} of the stub 43 coincides with the center O₃₂ₐ of a slot 32a.

A surface current is generated on the substrate 31a of the plane antenna plate 31 by microwaves which have been propagated from the coaxial waveguide 37a to the center of the plane antenna plate 31, as described above. While the surface current flows radially outward, it is blocked by slots 32, and an electric charge is induced at the edges of the slots 32. The electric charge acts as a new microwave generation source. Such an electric charge is likely to accumulate in the longitudinal center of a slot 32, and therefore the electric field is likely to concentrate in the center of the slot 32. In the embodiments shown in FIGS. 10 and 11, the stub 43 is disposed right above the center O₃₂ₐ or O_{32b} of a slot 32a or 32b to reduce the electric field concentration around the center O₃₂ₐ or O_{32b}.

By disposing the stub 43 such that the center O_{S} of the stub 43 overlaps with the center O₃₂ₐ or O_{32b} of a slot 32a or 32b which constitutes a slot pair arranged outermost in the plane antenna plate 31 as shown in FIG. 10 or 11, the lower slot 32 and the upper stub 43 can be made to vertically face each other with the retardation plate 33 interposed therebetween. Further, as shown in FIGS. 10 and 11, it is desirable that the stub 43 be disposed such that the hollow portion of the stub 43 vertically overlaps with the entire opening of the slot 32. Such arrangement of the stub 43 can upwardly expand the electric field existing near the slot 32. This can effectively prevent concentration or localization of the electric field over the plane antenna plate 31. By thus disposing the stub 43 such that in a plan view, the center O_{S} of the stub 43 coincides with the center O₃₂ₐ or O_{32b} of the slot 32a or 32b, it becomes possible to adjust and equalize the distribution of electric field in the interior space of the chamber 1 positioned below the plane antenna plate 31, thereby producing a uniform plasma in the chamber 1. It is also possible to dispose the stub 43 such that in a plan view, the center O_{S} of the stub 43 positions between two slot pairs.

In the embodiments shown in FIGS. 10 and 11, the center O₃₂ₐ or O_{32b} of the slot 32a or 32b, constituting an outermost slot pair, positions on a straight line X extending from the center O_{A} of the plane antenna plate 31 and passing through the centers O_{32c}, O_{32d} of slots 32a, 32b which constitute an inner slot pair (a plurality of inner pairs are possible, though only one pair is shown in FIGS. 10 through 12).

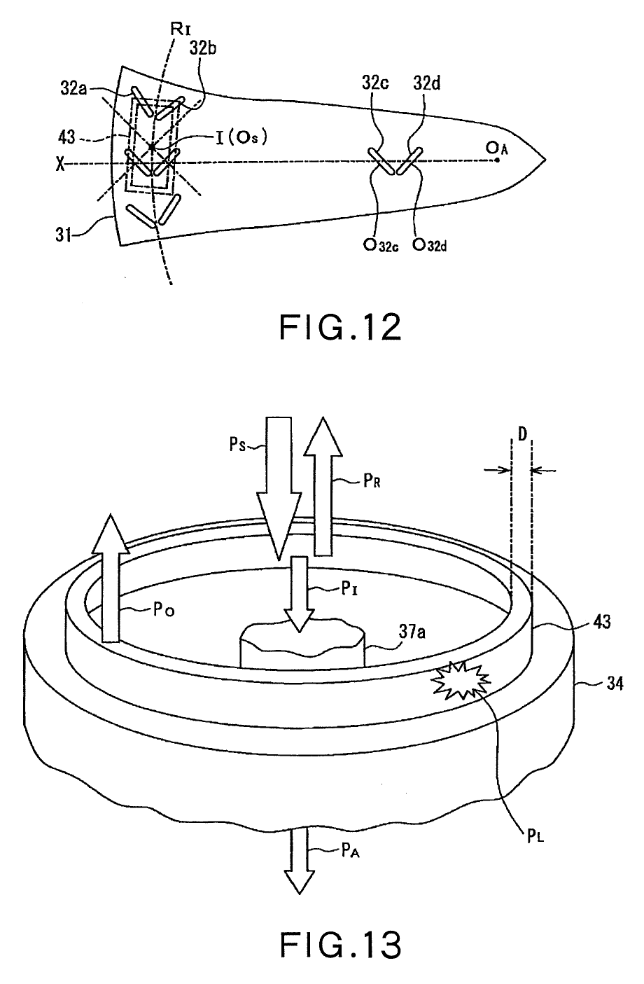

FIG. 12 illustrates an embodiment in which the center O_{S} of the stub 43 is aligned with an intersection I of two perpendiculars from the centers of slots 32a, 32b to their longitudinal directions, the slots 32a, 32b constituting a slot pair arranged outermost in a peripheral portion of the plane antenna plate 31. Thus, the stub 43 is disposed such that it positions over the intersection I, with the center O_{S} of the stub 43 coinciding with the intersection I in a plan view. It is also possible to dispose the stub 43 such that in a plan view, the center of the stub 43 positions on an arc R₁ connecting such intersections I in the circumferential direction of the plane antenna plate 31. It is also possible to dispose the stub 43 such that, in a plan view, the center O_{S} of the stub 43 positions between the two slots.

The stub 43 is preferably disposed such that in a plan view, the center of the stub 43 positions in an annular area between a first imaginary circle, connecting the longitudinal outer ends of the outer slots 32a of the outermost slot pairs and centered at the center O_{A} of the plane antenna plate 31, and a second imaginary circle, connecting the longitudinal inner ends of the inner slots 32b of the outermost slot pairs and centered at the center O_{A} of the plane antenna plate 31, and at least part of at least one slot overlaps with the stub 43.

For the three manners of arrangement of the stub 43 illustrated in FIGS. 10 through 12, the influence on the power of microwaves supplied to the chamber 1 of the plasma processing apparatus 100 and on the distribution of electric field was examined by simulation. The results are shown in Table 1.

<Simulation Conditions 1>

Simulation conditions are as follows:

Software used: COMSOL (trade name), manufacture by Comsol Inc.

Radial arrangement: An annular stub 43 as schematically shown in FIG. 13 was simulated. The annular stub 43 was set such that an arc extending radially centrally in the stub 43, with the distance to the inner and outer peripheries of the stub 43 being half the width D (D/2) of the stub 43, positions right above the arc R_{32b} shown in FIG. 10, right above the arc R₁ shown in FIG. 12, or right above the arc R₃₂ₐ shown in FIG. 11. The radius of each arc (horizontal distance from the vertical axis passing through the center O_{A} of the plane antenna plate 31) was set as follows: arc R_{32b}, 184 mm; arc R₁, 200 mm; and R₃₂ₐ, 215 mm.

Stub: An annular stub 43 whose top is closed and an annular stub 43 whose top is open were simulated. The vertical height of each stub 43 from the upper surface of the retardation plate 33 was set at 115.5 mm (3λ/4).

Boundary condition: perfect conductor

Plasma electron density: The plasma density was set such that it reaches 1×10^{12/cm}³ at a level 1 cm below the transmissive plate 28, and that the value is maintained in the plasma positioned below the level.

Dielectric constant: set at 4.2 (SiO₂), 1.0 (air)

Pressure: set at 13.3 Pa (100 mTorr)

Temperature: set at 500° C.

Transmissive pate: set as an arch-shaped quartz plate

Plane antenna plate: set as a plate having slot pairs arranged in two inner and outer concentric circles, each slot pair being comprised of two slots arranged in an L shape

In this simulation, the balance of the following microwave powers shown in FIG. 13 was calculated: the power of microwaves supplied from the microwave generator 39 to the waveguide 37 (supply power) P_{S}; the net power of microwaves supplied from the coaxial waveguide 37a into the chamber 1 (introduction power) P_{I}; the power of microwaves discharged from the stab 43 to the outside (discharge power) P_{O}; the power of microwaves which pass through the transmissive plate 28 and are absorbed (used) in a plasma generated in the chamber 1 (absorption power) P_{A}; the power of microwaves lost e.g. in the wall surface of the stub 43 (loss power) P_{L}; and the power of microwaves reflected to the coaxial waveguide 37a (reflection power) P_{R}. The calculation was performed by setting the supply power P_{S} at 2000 W and using the following equations:

P_{L}=P_{I}−P_{O}−P_{A}; P_{R}=P_{S}−P_{I}

In table 1, the “arrangement D1” corresponds to the arrangement shown in FIG. 10: The annular stub 43 was arranged such that the radius of the stub 43 is identical to the distance (184 mm) from the center O_{A} of the plane antenna plate 31 to the center O_{32b} of the slot 32b. The “arrangement D2” corresponds to the arrangement shown in FIG. 12: The annular stub 43 was arranged such that the radius of the stub 43 is identical to the distance (200 mm) from the center O_{A} of the plane antenna plate 31 to the intersection I. The “arrangement D3” corresponds to the arrangement shown in FIG. 11: The annular stub 43 was arranged such that the radius of the stub 43 is identical to the distance (215 mm) from the center O_{A} of the plane antenna plate 31 to the center O₃₂ₐ of the slot 32a. For comparison, a simulation was carried out under the same conditions, but without using the stub 43.

TABLE 1

| | Power balance [W] | | | | | | |
|---|---|---|---|---|---|---|---|
| | | Closed | | | Open | | |
| | No | Arrangement | Arrangement | Arrangement | Arrangement | Arrangement | Arrangement |
| | Stub | D1 | D2 | D3 | D1 | D2 | D3 |
| P_{I} | 190 | 722 | 333 | 696 | 869 | 720 | 1044 |
| P_{O} | — | — | — | — | 625 | 393 | 719 |
| P_{A} | 169 | 700 | 307 | 675 | 207 | 291 | 283 |
| P_{L} | 21 | 22 | 26 | 21 | 37 | 36 | 42 |
| P_{R} | 1810 | 1278 | 1667 | 1304 | 1131 | 1280 | 956 |

As can be seen from the data in Table 1, compared to the case where the stub 43 is not provided, the absorption power P_{A} is higher and the reflection power P_{R} is lower generally for the arrangements D1 to D3 whether the top of the stub 43 is closed or opened. The data thus demonstrates that the provision of the stub 43 can reduce reflected waves in the waveguide and can efficiently supply microwaves into the chamber 1.

In comparison of the case where the top of the stub 43 is closed with the case where the stub is open, the discharge power P_{O} is higher and the absorption power P_{A} is lower in the latter (open) case. This indicates that microwaves can be more efficiently supplied into the chamber 1 by making the top of the stub 43 closed.

In reviewing the data in table 1 for the arrangements of the stub 43 solely in the case where the top is closed, in view of the above results, the arrangement D1 shows the highest absorption power P_{A}, 700 W, and the arrangement D3 shows the next value 675 W, whereas the absorption power P_{A} is as low as 307 W for the arrangement D2.

With reference to the reflection power P_{R} of microwaves reflected into the waveguide 37, the arrangement D1 shows the lowest value 1278 W and the arrangement D3 shows the next value 1304 W, whereas the arrangement D2 shows a higher value of 1667 W, indicating the generation of a larger amount of reflected waves as compared to the arrangements D1 and D3.

The distribution of electric field was imaged and analyzed for the following areas: a cross-section of the stub 43 (at a position 0.5 mm above the lower end); the upper surface of the retardation plate 33, a central cross-section of the retardation plate 33 (at a position corresponding to the thickness×½); a central cross-section of the plane antenna plate 31 (at a position corresponding to the thickness×½); a cross-section of the transmissive plate 28 (at a position 9 mm below the upper end); the lower surface of the transmissive plate 28 (flat area); the interface between the transmissive pate 28 (including a curved area) and the interior space of the chamber 1; and an area in the chamber 1, positioning 0.5 mm below the lower surface of the transmissive plate 28. As a result, with reference to the distribution of electric field in the central cross-section of the plane antenna plate 31, for example, it was found that a region of strong electric field exists locally around the inner slot pairs in the arrangement D2, whereas in the arrangements D1 and D3, a strong electric field is distributed not only over a region around the inner slot pairs, but uniformly over the entire plane antenna plate 31, including a region around the outer slot pairs (diagrammatic illustration of the results omitted). Similar simulation results were obtained for the distribution of electric field in the other areas tested. It was also found that a region of strong electric field tends to exist radially, extending radially from the center O_{A} of the plane antenna plate 31, passing through the inner slot pairs and reaching to the outer slot pairs.

The above simulation results demonstrate that microwaves can be efficiently supplied into the chamber 1 by providing the stub 43 which adjusts the distribution of an electric field generated over the plane antenna plate 31 constituting the flat waveguide.

The simulation results also demonstrates that compared to the case where the top of the stub 43 is open, microwaves can be more efficiently introduced into the chamber 1 by making the top of the stub 43 closed.

It is also revealed that the stub 43 is preferably disposed such that in a plan view, the hollow portion of the stub 43 overlaps with the outermost slot pairs, and more preferably, overlaps with the outer slots 32 or inner slots 32b of the outermost slot pairs. In particular, it is revealed that the stub is most preferably disposed in the manner of the arrangement D1 (see FIG. 10) in which the center O_{S} of the stub 43 is aligned with the center O_{32b} of the inner slot 32b of an outermost slot pair of the plane antenna plate 31, followed by the arrangement D3 (see FIG. 11) in which the center O_{S} of the stub 43 is aligned with the center O₃₂ₐ of the outer slot 32a of an outermost slot pair of the plane antenna plate 31.

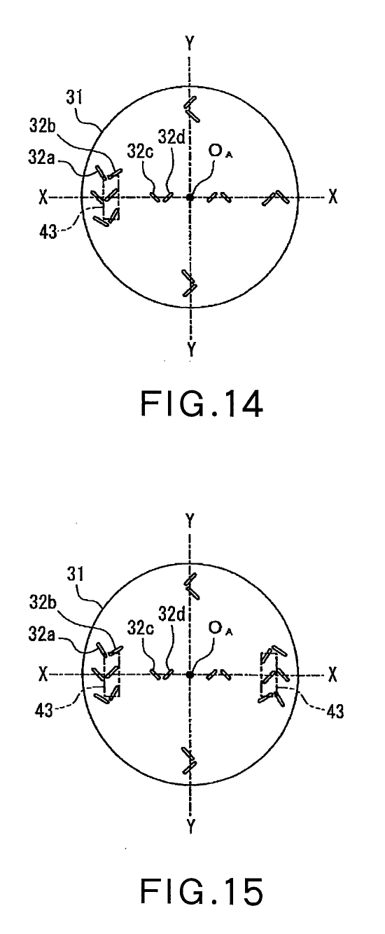

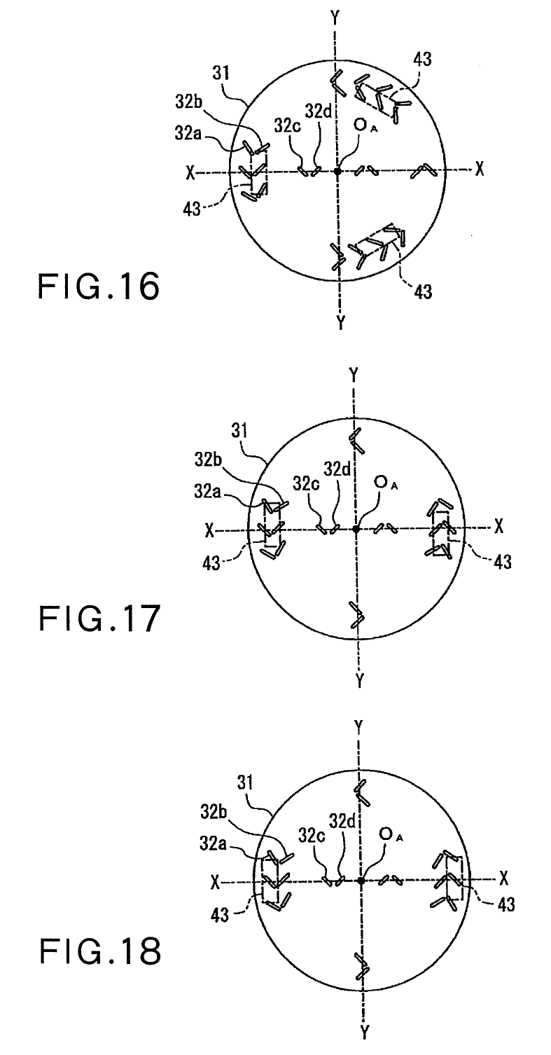

The number of stubs 43 will now be described with reference to FIGS. 14 through 19. FIG. 14 illustrates an arrangement of one hollow block-shaped stub 43, FIG. 15 illustrates an arrangement of two hollow block-shaped stubs 43, and FIG. 16 illustrates an arrangement of three hollow block-shaped stubs 43, the stubs being shown together with the overlapping plane antenna plate 31. FIGS. 17 through 19 illustrate variations of the arrangement of two stubs 43, shown in FIG. 15. In FIGS. 14 through 19, only some of the slots 32 of the plane antenna plate 31 are shown, and non-illustrative slots 32 are omitted. It is preferred to arrange at least two stubs 43 as shown in FIGS. 15 and 16. It is particularly preferred to arrange two stubs 43 symmetrically with respect to the center O_{A} of the plane antenna plate 31 as shown in FIG. 15. The effect of equalizing the distribution of electric field in the vicinity of the plane antenna plate 31 is highest when two stubs 43 are thus arranged symmetrically in the radial direction of the plane antenna plate 31. The effect of equalizing the distribution of electric field does not necessarily increase, or rather can decrease if an unnecessarily large number of stubs 43 are arranged. Further, the arrangement of an unnecessarily large number of stubs 43 increases the number of parts of the plasma processing apparatus 100, which may increase the apparatus cost. Therefore, the number of stubs 43 preferably is 2 to 6.

Microwaves are introduced from the coaxial waveguide 37a into the vicinity of the center O_{A} of the plane antenna plate 31, and propagates in the form of a circular polarized wave radially outward through the waveguide, formed by the plane antenna plate 31 and the cover 34, generating a surface current radially along radially-arranged slots 32. Therefore, when the slot pairs are arranged in concentric circles in the plane antenna plate 31, it is preferred to arrange the stub(s) 43 along a line along which slots 32 are arranged in the radial direction. For example, FIGS. 14 through 16 illustrate an X-X line along which slots 32 line up in the radial direction. The X-X line pass through the center O_{A} of the plane antenna plate 31 and inner slot pairs (only two pairs are illustrated) each comprised of slots 32c, 32d, arranged on opposite sides of the center O_{A}, and connects to outermost slot pairs each comprised of slots 32a, 32b, arranged on opposite sides of the center O_{A}. On the other hand, the Y-Y line shown in FIGS. 14 through 16 is a straight line passing through the center O_{A} of the plane antenna plate 31 and connecting to outermost slot pairs (slots 32a, 32b), arranged on opposite sides of the center O_{A}, without passing through inner slot pairs (slots 32c, 32d). Though the stubs 43 may be arranged on either the X-X line or the Y-Y line, they are preferably disposed on the X-X line. Thus, when two stubs 43 are arranged, it is preferred to oppositely arrange the stubs 43 right above the X-X line as shown in FIG. 15, rather than arranging the two stubs 43 right above the Y-Y line.

For the three manners of arrangement of the stub 43 illustrated in FIGS. 14 through 16, the influence on the power of microwaves supplied to the chamber 1 of the plasma processing apparatus 100 and on the distribution of electric field was examined by simulation. The results are shown in Table 2.

<Simulation Conditions 2>

Simulation conditions are as follows:

Radial arrangement: One, two or three hollow block-shaped stubs 43 were set such that in a plan view, the center of the stub 43 coincides with the center O_{32b} of the inner slot 32b of an outermost slot pair of the plane antenna plate 31 (see FIG. 10, arrangement D1).

Stub: set as a top-closed stub with a rectangular cross-section, having a longitudinal length of 100 mm, a width of 35 mm and a height of 115.5 mm (3λ/4) from the upper surface of the retardation plate.

The other conditions are the same as the simulation conditions 1, and hence a description thereof is omitted.

In this simulation, the balance of the introduction power P_{I}, the absorption power P_{A}, the loss power P_{L} and the reflection power P_{R} (see FIG. 13) was calculated by setting the supply power P_{S} at 2000 W and using the following equations: P_{L}=P_{I}−P_{A}; P_{R}=P_{S}−P_{I}.

In Table 2, the “arrangement number N1” represents the arrangement of one stub 43 at the position shown in FIG. 14; the “arrangement number N2” represents the arrangement of two stubs 43 at the opposite positions shown in FIG. 15; and the “arrangement number N3” represents the arrangement of three stubs 43 at the positions circumferentially spaced 120° apart from each other, shown in FIG. 16. For comparison, the above-described simulation results in the case of no use of a stub are reproduced in Table 2.

TABLE 2

Power balance [W]

| | | Closed | | |
|---|---|---|---|---|
| | | Arrangement | Arrangement | Arrangement |
| | No stub | Number N1 | Number N2 | Number N3 |
| P_{I} | 190 | 411 | 1611 | 843 |
| P_{A} | 169 | 384 | 1559 | 882 |
| P_{L} | 21 | 27 | 52 | 39 |
| P_{R} | 1810 | 1589 | 389 | 1157 |

Regarding the data in Table 2, the arrangement number N2 shows the highest absorption power P_{A}, 1559 W, and the arrangement number N3 shows the next value 882 W, whereas the arrangement number N1 shows the absorption power P_{A} 382 W which is the lowest among the cases where the stub(s) 43 is provided. With reference to the reflection power P_{R}, the arrangement number N2 shows the lowest value 389 W and the arrangement number N3 shows the next value 1157 W, whereas the arrangement number N1 shows a larger value of 1587 W, indicating inferiority to the arrangement numbers N1 and N3.

The distribution of electric field was imaged and analyzed for the following areas: a cross-section of the stub 43 (at a position 0.5 mm above the lower end); the upper surface of the retardation plate 33, a central cross-section of the retardation plate 33 (at a position corresponding to the thickness×½); a central cross-section of the plane antenna plate 31 (at a position corresponding to the thickness×½); a cross-section of the transmissive plate 28 (at a position 9 mm below the upper end); the lower surface of the transmissive plate 28 (flat area); and the interface between the transmissive pate 28 (including a curved area) and the interior space of the chamber 1. The results revealed more uniform electric field distribution for the arrangement numbers N2 and N3 as compared to the arrangement number N1 (diagrammatic illustration of the results omitted).

The above simulation results reveal that arranging a plurality of, for example, two or three, stubs 43 is preferred rather than arranging one stub 43. Further, as can be seen from comparison with the data in table 1, compared to the provision of the annular stub 43, the absorption power P_{A} is significantly higher when the two or three independent hollow block-shaped stubs 43 are provided. The above data thus demonstrates that by providing at least two stubs 43 above the plane antenna plate 31 constituting the flat waveguide, the distribution of an electric field generated over the plane antenna plate 31 can be adjusted and equalized, and microwaves can be efficiently supplied into the chamber 1.

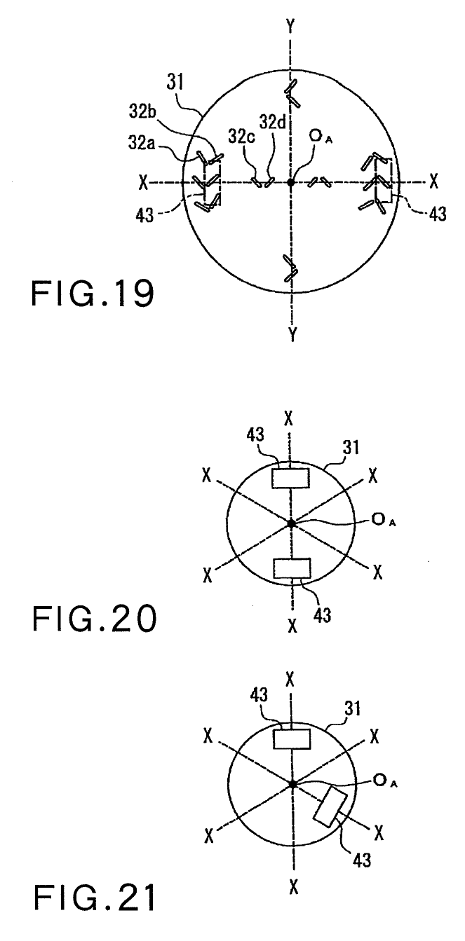

In the embodiments shown in FIGS. 14 through 16, the hollow block-shaped stub 43 is disposed over the inner slot 32b of an outermost slot pair. However, it is possible to dispose the stub 43 over an intermediate position between the slot 32a and the slot 32b of an outermost slot pair, as shown in FIG. 17. It is also possible to dispose the stub 43 over the outer slot 32a of an outermost slot pair, as shown in FIG. 18. Further, as shown in FIG. 19, it is possible to dispose one of the opposing stubs 43 over the inner slot 32b of an outermost slot pair, and to dispose the other one over the outer slot 32a of an outermost slot pair positioning on the opposite side of the center O_{A} from the former slot pair. While FIGS. 17 through 19 illustrate the cases where two stubs 43 are arranged symmetrically in the radial direction of the plane antenna plate 31, the same manners of arrangement are possible for the case of arranging one stub 43 (see FIG. 14) and for the case of arranging three stubs 43 (see FIG. 16).

The influence of the arrangement and number of stubs 43 on the power of microwaves supplied to the chamber 1 of the plasma processing apparatus 100 and on the distribution of electric field was examined in further detail by simulation. The results are shown in Table 3.

<Simulation Conditions 3>

Simulation conditions are as follows:

Circumferential arrangement: Simulation was carried out for seven manners of the arrangement and number of stubs 43 as shown in FIGS. 20 through 26. In FIGS. 20 through 26, the arrangement of stubs 43 with respect to the plane antenna plate 31 is shown in a simplified schematic manner. In each Figure, diagrammatic illustration of slots 32 is omitted, and the radial arrangement of slots 32 is shown by the line segments X-X each passing through the center O_{A} of the plane antenna plate 31 and connecting the slots 32c, 32d of opposing inner slot pairs and the slots 32a, 32b of opposing outermost slot pairs.

Radial arrangement: Each stub 43 was set such that in a plan view, the center of the stub 43 coincides with the center O_{32b} of the inner slot 32b of an outermost slot pair of the plane antenna plate 31 (see FIG. 10, arrangement D1).

The other conditions are the same as the simulation conditions 2, and hence a description thereof is omitted.

In this simulation, the balance of the introduction power P_{I}, the absorption power P_{A}, the loss power P_{L} and the reflection power P_{R} was calculated by setting the supply power P_{S} at 2000 W and using the following equations: P_{L}=P_{I}−P_{A}; P_{R}=P_{S}−P_{I}.

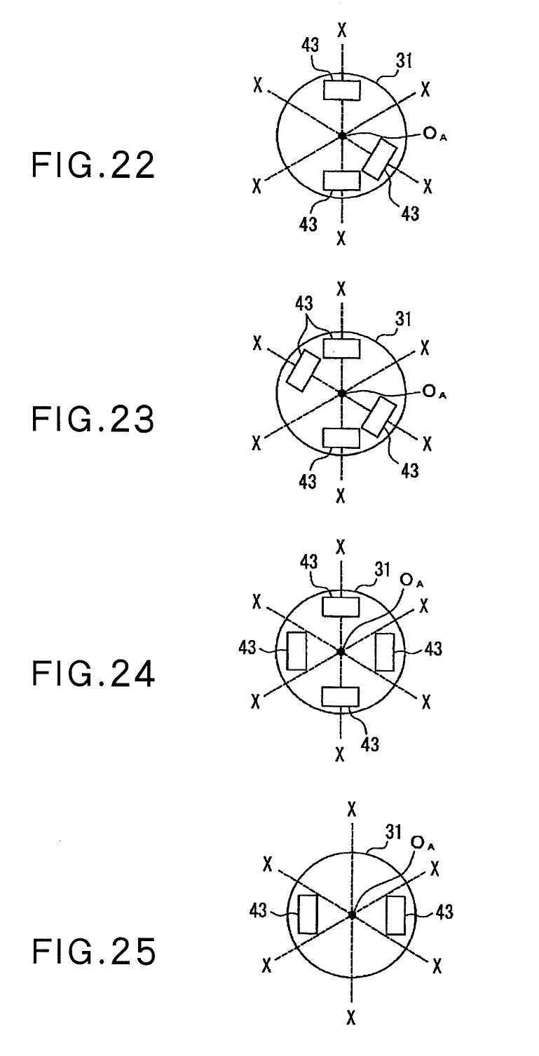

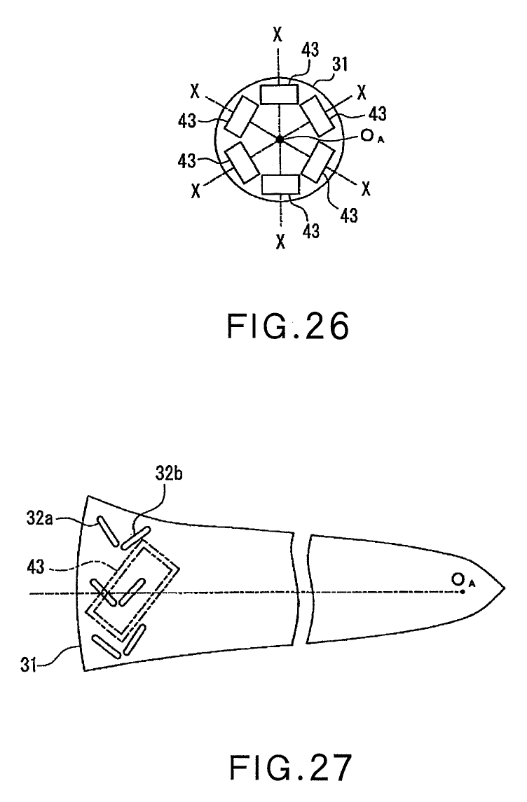

In the “arrangement C1” shown in Table 3 below, two stubs 43 are arranged at opposite positions over the line X-X as shown in FIG. 20. In the “arrangement C2”, as shown in FIG. 21, two stubs 43 are arranged asymmetrically with respect to the center O_{A} of the plane antenna plate 31. The two stubs 43 are disposed at positions circumferentially spaced 120° apart from each other. In the “arrangement C3”, as shown in FIG. 22, three stubs 43 are arranged at asymmetric positions. Two of the three stubs 43 are arranged at opposite positions over the line X-X as in the arrangement C1, while the other stub 43 is disposed over another line X-X making an angle of 60° with the former line. In the “arrangement C4”, as shown in FIG. 23, four stubs 43 are arranged over two lines X-X. The two lines intersect at an angle of 60° at the center O_{A} of the plane antenna plate 31. In the “arrangement C5”, as shown in FIG. 24, four stubs 43 are arranged at positions circumferentially spaced 90° apart from each other. Two of the four stubs 43 are oppositely disposed off the lines X-X (and over the line Y-Y shown in FIGS. 14 through 19). In the “arrangement C6”, as shown in FIG. 25, two stubs 43 are oppositely disposed off the lines X-X (and over the line Y-Y shown in FIGS. 14 through 19). In the “arrangement C7”, as shown in FIG. 26, six stubs 43 are circumferentially evenly arranged over the lines X-X circumferentially spaced 60° apart from each other. For comparison, the above-described simulation results in the case of no use of a stub are reproduced in Table 3.

TABLE 3

| | Power balance [W] | | | | | | | |
|---|---|---|---|---|---|---|---|---|
| | | Closed | | | | | | |
| | No | Arrangement | Arrangement | Arrangement | Arrangement | Arrangement | Arrangement | Arrangement |
| | Stub | C1 | C2 | C3 | C4 | C5 | C6 | C7 |
| P_{I} | 190 | 1611 | 643 | 1658 | 873 | 1462 | 1447 | 682 |
| P_{A} | 169 | 1559 | 611 | 1605 | 835 | 1410 | 1398 | 649 |
| P_{L} | 21 | 52 | 32 | 53 | 38 | 52 | 49 | 33 |
| P_{R} | 1810 | 389 | 1357 | 342 | 1127 | 538 | 553 | 1318 |

As can be seen from the data in FIG. 3, compared to the case where the stub 43 is not provided, better results were obtained for any of the arrangements C1 to C7. The absorption power P_{A} for the arrangement C3 (FIG. 22), 1605 W, is the highest, followed by the nearly equal value 1559 W for the arrangement C1 (FIG. 20). The absorption powers P_{A} for the arrangement C5 (FIG. 24) and the arrangement C6 (FIG. 25) follow those of the arrangement C3 and the arrangement C1. On the other hand, any of the arrangements C2, C4 and C7 shows a lower absorption power P_{A} than the arrangements C1, C3, C5 and C6. The absorption power P_{A} is the lowest for the arrangement C2 (FIG. 21) in which two stubs 43 are arranged asymmetrically with respect to the center O_{A} of the plane antenna plate 31. The adsorption powers P_{A} is low also for the arrangement C4 (FIG. 23) in which four stubs 43 are arranged such that adjacent two stubs are circumferentially spaced 60° apart from each other and for the arrangement C7 (FIG. 26) in which six stubs 43 are circumferentially arranged. The results for the arrangements C4 and C7 fell short of expectations.

The reflection powers P_{R} are nearly equally low and good for the arrangements C1, C3, C5 and C6. On the other hand, the reflection powers P_{R} for the arrangements C2, C4 and C7 are higher, and thus the reflectances are higher, compared to the arrangements C1, C3, C5 and C6.

In comparison between the arrangements C1 and C6 both using two stubs 43, better results were achieved by the arrangement C1 in which the stubs 43 are arranged over the line X-X diametrically connecting the center O_{A} of the plane antenna plate 31, inner slot pairs and outer slot pairs, compared to the arrangement C6 in which the stubs 43 are arranged over the line Y-Y diametrically connecting the center O_{A} of the plane antenna plate 31 and outer slot pairs without passing through inner slot pairs. In comparison between the arrangements C4 and C5 both using four stubs 43, much better results were achieved by the arrangement C5 in which the stubs 43 are arranged evenly in the circumferential direction of the plane antenna plate 31.

The distribution of electric field was imaged and analyzed for the following areas: a cross-section of the stub 43 (at a position 0.5 mm above the lower end); the upper surface of the retardation plate 33, a central cross-section of the retardation plate 33 (at a position corresponding to the thickness×½); a central cross-section of the plane antenna plate 31 (at a position corresponding to the thickness×½); a cross-section of the transmissive plate 28 (at a position 9 mm below the upper end); the lower surface of the transmissive plate 28 (flat area); and the interface between the transmissive pate 28 (including a curved area) and the interior space of the chamber 1. The results revealed the most uniform electric field distribution for the arrangements C3 and C1, followed by the arrangements C5 and C6 (diagrammatic illustration of the results omitted).

The above simulation results reveal that stubs 43 are preferably arranged such that they position over the line(s) (line X-X) diametrically connecting the center O_{A} of the plane antenna plate 31, inner slot pairs and outer slot pairs, and that they are symmetrical with respect to the center O_{A}. The results also reveal that even when stubs 43 are arranged in such a manner, the efficiency of absorption of microwaves in plasma will lower when more than a certain number of stubs 43 are provided. Thus, it turns out that the number of stubs 43 is preferably in the range of 2 to 4.

A simulation experiment was carried out by introducing a gas into the plasma processing apparatus 100 and generating a plasma.

Simulation conditions are as follows:

<Simulation Conditions 4>

Radial arrangement: An annular top-closed stub 43 was simulated. The annular stub 43 was set such that an arc extending radially centrally in the stub 43, with the distance to the inner and outer peripheries of the stub 43 being half the width D (D/2) of the stub 43 (D=30 mm), positions at a horizontal distance of 184 mm from the vertical axis passing through the center O_{A} of the plane antenna plate 31 (see FIG. 13).

Stub: The height of the stub 43 from the upper surface of the retardation plate 33 was set at 115.5 mm (3λ/4).

The power P_{A} (absorption power) of microwaves which, after passing through the transmissive plate 28, are absorbed in the plasma generated in the chamber 1 was 641 W when the stub 43 was not provided, whereas the power P_{A} was 1373 W, and was thus much better, when the stub 43 was provided.

Further, the electron density distribution and the electron temperature distribution in the plasma in the chamber 1 were imaged. As a result, compared to the case where the stub 43 is not provided, a uniform low-electron temperature, high-electron density plasma region just under the transmissive plate 28 was found to be wider in the radial direction of the plane antenna plate 31 in the case where the stub 43 is provided.

Further, the distribution of N radicals and the distribution of N ions in the chamber 1 were imaged. As a result, compared to the case where the stub 43 is not provided, both N radicals and N ions were found to be uniformly distributed just under the transmissive plate 28 over a wider area in the radial direction of the plane antenna plate 31 in the case where the stub 43 is provided.

The simulation results thus verify that the provision of the stub 43 can equalize a plasma in the chamber 1.

While the present invention has been described with reference to preferred embodiments, it is understood that the present invention is not limited to the embodiments, but is capable of various modifications. For example, though in the above embodiments the stub 43 is arranged such that the longitudinal direction of the stub 43 is perpendicular to the radial direction of the plane antenna plate 31, the present invention is not limited to such an arrangement manner. For example, the stub 43 may be arranged such that the longitudinal direction of the stub 32 coincides with the longitudinal direction of a slot 32, as shown in FIG. 27. Further, instead of a position over a slot 32a or 32b of an outermost slot pair, it is possible to dispose the stub 43 over any slot of the plane antenna plate 31 if the electric field intensity is abnormally high at the slot.

The cross-sectional shape of the stub 43 is not limited to a rectangular shape: a square shape, for example, may be possible. Further, the stub 43 may be formed in a cylindrical or annular shape that surrounds the coaxial waveguide 37a.

The plasma processing apparatus 100 provided with the stub(s) 43 of the present invention can be applied to a plasma oxidation processing apparatus, a plasma nitridation processing apparatus, a plasma CVD processing apparatus, a plasma etching apparatus, a plasma ashing apparatus, etc. Further, the plasma processing apparatus 100 provided with the stub(s) 43 of the present invention can also be applied to a plasma processing apparatus which processes a processing object other than a semiconductor wafer, for example, a substrate for a flat panel display, such as a liquid crystal display or an organic EL display.

### Experimental Examples

An experiment was conducted to verify the fact that processing uniformity can be enhanced by adjusting the height of a stub(s). The method and results of the experiment will now be described.

A plasma processing apparatus which was used in the experiment is first described with reference to FIG. 28.

The plasma processing apparatus shown in FIG. 28 differs from the plasma processing apparatus shown in FIG. 1 only in the following respects: First, a protrusion 28a is provided in the center of the lower surface of the transmissive plate 28. Further, instead of the cover ring 4, a cover 4a which covers the entire upper surface of the stage 2 is provided. Positioning of a wafer W is performed by means of a guide 4b provided on the upper surface of the cover 4a. Instead of the stub(s) 43, four stubs 43A, each capable of changing the effective stub height, are provided. A movable body 43a is provided in the interior of each stub 43A; and the movable body 43a can be moved vertically through a bolt/nut structure (detailed structure not shown) by turning a handle 43b. As with the lid 44 of the stub 43, the movable body 43a determines the effective tube length of the stub. Thus, the substantial stub height (H) can be changed by vertically moving the movable body 43a.

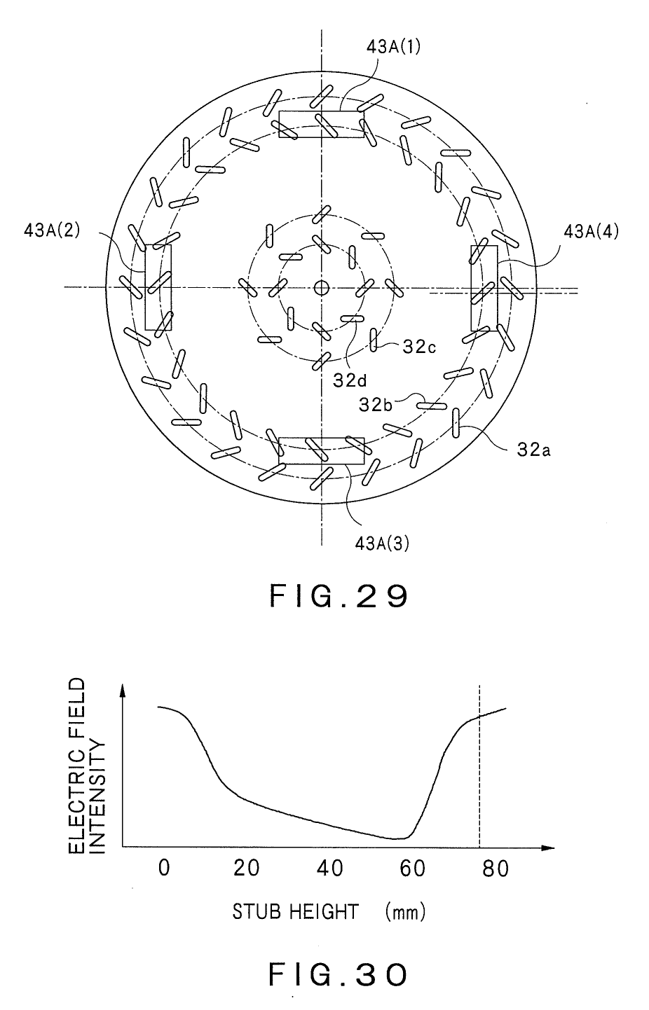

As shown in FIG. 29, 24 slot pairs are formed in the peripheral area and 8 slot pairs are formed in the central area of the substrate 31a of the plane antenna plate 31. The substrate 31a has an intermediate area, having no slot 32, between the peripheral area and the central area. The stubs 43A are arranged at 90 degree intervals on a pitch circle having a predetermined diameter. In FIG. 29 is shown the outline of the inner wall surface of each stub 43A. In FIG. 29, in a plan view, a straight line, extending in the diametric direction of the plane antenna plate and passing through the centers of the outer slots 32a of opposite peripheral slot pairs and the centers of the both slots 32c, 32d of opposite central slot pairs, passes through the center of each stub 43A. Further, at least one of the inner slots 32b of peripheral slot pairs overlaps with each stub 43A (in particular, the whole of the one inner slot 32b is fully included in the area of the internal space of the stub 43A, and two inner slots each partly overlap with the area of the internal space of the stub 43A).

The graph of FIG. 30 shows the relationship between the height H of a stub and the electric field intensity in the ceiling plate portion under the stub at a microwave frequency of 2.45 GHz. As can be seen from the graph, the electric field intensity decrease with increase in the stub height H in the stub height range of 20 to 60 mm, and the change in the electric field intensity with change in the stub height H is relatively moderate. Thus, to change the stub height H in the range of 20 to 60 mm is suited for fine adjustment of the distribution of electric field. Though not shown in FIG. 30, the electric field intensity changes periodically per a change of λ/2 (λ denotes in-tube wavelength) in the stub height H.

In this experiment, a semiconductor wafer, having a 30 angstrom thick thermally-oxidized SiO₂ film formed in the surface, was prepared. The wafer was subjected to plasma nitridation using the microwave plasma processing apparatus described above with reference to FIGS. 28 and 29.

Processing conditions in a first experiment are as follows:

Ar gas flow rate: 1000 sccm

N₂ gas flow rate: 2000 sccm

Processing pressure: 25 Pa

Microwave power: 1900 W (0.97 W/cm²)

Wafer temperature: 500° C.

Processing time: 50 sec

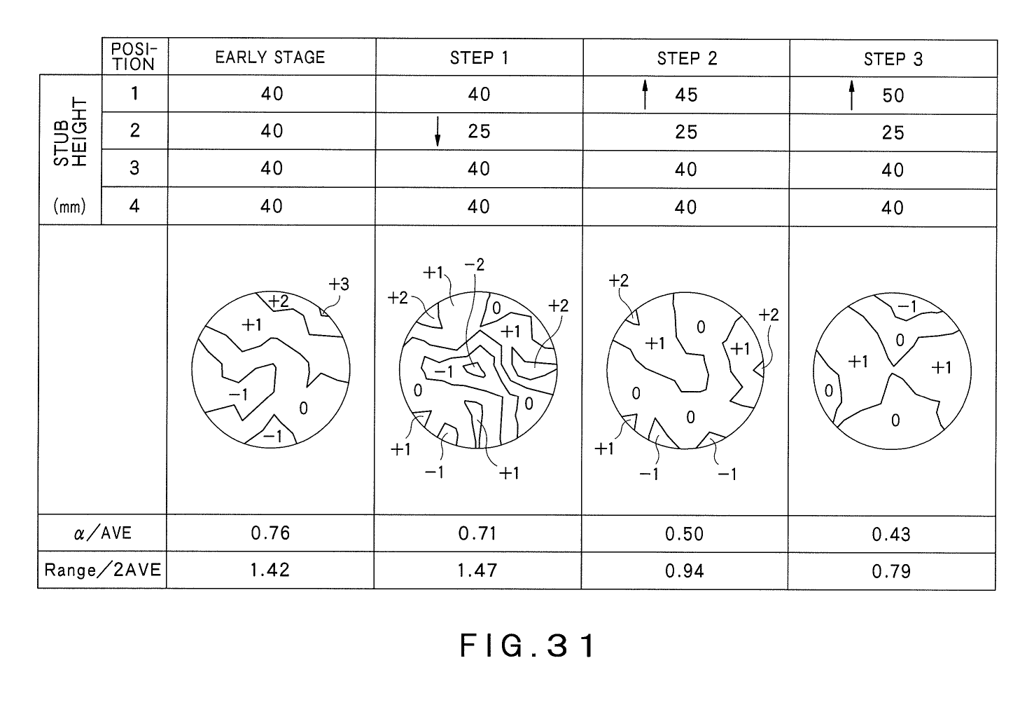

First, plasma nitridation was carried out with the heights of all the four stubs set at 40 mm (i.e. median of the 20-60 mm range). The concentration of nitrogen was measured by XPS (X-ray photoelectron spectroscopy) at 25 points in the surface of the processed wafer. The results are shown in the left column (“early stage”) of the table of FIG. 31. In the table, the upper rows indicate the heights of the stubs at predetermined positions, the middle row indicates maps each showing the distribution of nitrogen concentration, and the lower rows indicate σ/AVE (standard deviation of nitrogen concentration/average nitrogen concentration) and Range/2AVE [(maximum nitrogen concentration−minimum nitrogen concentration)/average nitrogen concentration×2], which are indices of the in-plane uniformity of processing. With reference to the positions of the stubs, the position “1” represents an upper position, “2” a right position, “3” a lower position and “4” a right position in each map (see FIG. 29). In the maps, the area “0” represents an area in which the nitrogen concentration is around the average, the areas “+1”, “+2”, “+3” represent areas in which the nitrogen concentration is higher than the average, and the areas “−1”, “−2” represent areas in which the nitrogen concentration is lower than the average, the numbering corresponding to the relative concentration level.

Following the policy of lowering the height of a stub positioning at a position corresponding to an area of low nitrogen concentration and raising the height of a stub positioning at a position corresponding to an area of high nitrogen concentration, the in-plane uniformity of nitrogen concentration was enhanced in a trial-and-error manner by changing the heights of stubs in steps 1 to 3 as shown in the table of FIG. 31. As can be seen from the table, the distribution of nitrogen concentration can be changed by changing the heights of stubs to change the distribution of electric field intensity. In the first experiment, a satisfactory in-plane uniformity was achieved by increasing the height of the stub at the position 1 from 40 mm to 50 mm and decreasing the height of the stub at the position 2 from 40 mm to 25 mm.

Using the same plasma processing apparatus as used in the first experiment, a second experiment was conducted under the following different processing conditions:

Ar gas flow rate: 750 sccm

N₂ gas flow rate: 200 sccm

Processing pressure: 25 Pa

Microwave power: 2000 W

Wafer temperature: 500° C.

Processing time: 50 sec

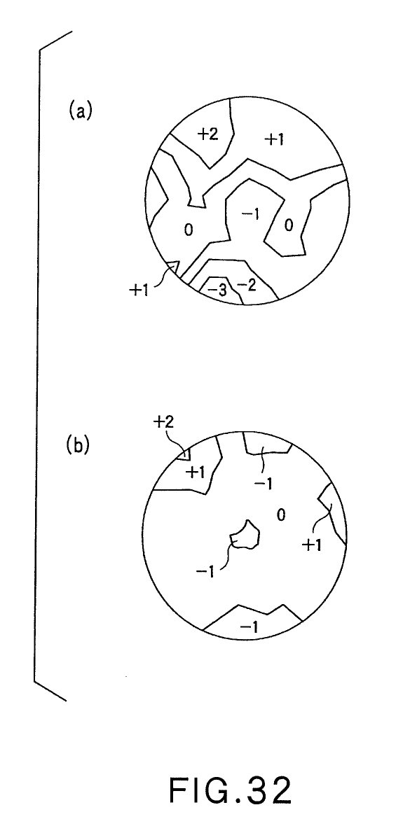

The results are shown in FIG. 32. FIG. 32(a) is a map showing the distribution of nitrogen concentration in the early stage, and FIG. 32(b) is a map showing the distribution of nitrogen concentration after the completion of adjustment. A description of the adjustment process is omitted. In the early stage, the stub height was 30 mm at all the positions 1, 2, 3, 4; and the σ/AVE value was 1.02 and the Range/2AVE value was 1.99. On the other hand, as a result of changing the stub height to 45 mm at the position 1, 20 mm at the position 2, 20 mm at the position 3, and 45 mm at the position 4, the σ/AVE value changed to 0.43 and the Range/2AVE value changed to 1.03. The results indicate significant enhancement in the in-plane uniformity. The results of the first and second experiments thus indicate that regardless of the difference in processing conditions, the distribution of nitrogen concentration can be changed by changing the heights of stubs to change the distribution of electric field intensity.

The distribution of electric field intensity can be changed by adjustment of the height of a stub(s) also under other processing conditions than the above-described ones (e.g. different processing pressures, different microwave powers). Further, uniform processing becomes possible by adjusting the height of a stub(s) to adjust the distribution of electric field intensity in various cases, including the cases of a different arrangement of slots, a different shape of ceiling plate, a different chamber, etc.

1. A plasma processing apparatus comprising:
an evacuable processing container for housing a processing object;
a transmissive plate hermetically mounted in a top opening of the processing container and which is transmissive to microwaves for plasma generation;
a plane antenna, disposed close to or in contact with an upper surface of the transmissive plate, for introducing microwaves into the processing container, said antenna including a plate-like substrate of conductive material, having a plurality of slots that penetrate through the substrate;
a conductive member covering from above the plane antenna;
a first waveguide, penetrating through the conductive member, for supplying microwaves from a microwave generation source to the plane antenna; and
at least one second waveguide for adjusting the distribution of electric field in the plane antenna,
wherein the plurality of slots are comprised of slot pairs of two slots and the slot pairs are arranged in concentric circles, and wherein the second waveguide is disposed over the center of a radially inner one of the two slots of an outermost slot pair.

2. The plasma processing apparatus according to claim 1, wherein the second waveguide is partly or wholly comprised of a hollow member having a cavity and inserted into the conductive member.

3. The plasma processing apparatus according to claim 1, wherein the second waveguide is partly or wholly comprised of an opening which penetrates through the conductive member.

4. The plasma processing apparatus according to claim 1, wherein the second waveguide is partly or wholly comprised of a recess formed in the conductive member.

5. The plasma processing apparatus according to claim 1, wherein the upper end of the second waveguide is closed.

6. The plasma processing apparatus according to claim 1, wherein the second waveguide is disposed over at least one of the plurality of slots.

7. (canceled)

8. The plasma processing apparatus according to claim 1, wherein in a plane view, the entire area of the opening of said at least one of the two slots of the slot pair is fully included in the area of the interior space of the second waveguide.

9. (canceled)

10. The plasma processing apparatus according to claim 1, wherein in a plane view, the center of the second waveguide positions on an arc connecting the centers of radially inner slots of outermost slot pairs.

11. The plasma processing apparatus according to claim 1, wherein in a plan view, the center of the second waveguide coincides with the center of the radially inner one of the two slots of the outermost slot pair.

12. A plasma processing apparatus comprising:
an evacuable processing container for housing a processing object;
a transmissive plate hermetically mounted in a top opening of the processing container and which is transmissive to microwaves for plasma generation;
a plane antenna, disposed close to or in contact with an upper surface of the transmissive plate, for introducing microwaves into the processing container, said antenna including a plate-like substrate of conductive material, having a plurality of slots that penetrate through the substrate;
a conductive member covering from above the plane antenna;
a first waveguide, penetrating through the conductive member, for supplying microwaves from a microwave generation source to the plane antenna; and
at least one second waveguide for adjusting the distribution of electric field in the plane antenna,
wherein the plurality of slots are comprised of slot pairs of two slots and the slot pairs are arranged in concentric circles, and wherein the second waveguide is disposed over the center of a radially outer one of the two slots of an outermost slot pair.

13. The plasma processing apparatus according to claim 12, wherein in a plane view, the center of the second waveguide positions on an arc connecting the centers of radially outer slots of outermost slot pairs.

14. The plasma processing apparatus according to claim 12, wherein in a plan view, the center of the second waveguide coincides with the center of the radially outer one of the two slots of the outermost slot pair.

15. The plasma processing apparatus according to claim 1, wherein a plurality of second waveguides are provided as said at least one second waveguide, and the number of the second waveguides is within the range of 2 to 4.

16. The plasma processing apparatus according to claim 15, wherein at least two of the plurality of second waveguides are arranged radially symmetrically with respect to the center of the plane antenna.

17. The plasma processing apparatus according to claim 16, wherein the plurality of second waveguides are each disposed over a line extending radially outward from the center of the plane antenna and connecting some slots of said plurality of slots.

18. The plasma processing apparatus according to claim 1, further comprising a retardation plate, disposed on the plane antenna, for adjusting the wavelength of microwaves to be supplied to the plane antenna.

19. The plasma processing apparatus according to claim 12, wherein a plurality of second waveguides are provided as said at least one second waveguide, and the number of the second waveguides is within the range of 2 to 4.

20. The plasma processing apparatus according to claim 19, wherein at least two of the plurality of second waveguides are arranged radially symmetrically with respect to the center of the plane antenna.

21. The plasma processing apparatus according to claim 20, wherein the plurality of second waveguides are each disposed over a line extending radially outward from the center of the plane antenna and connecting some slots of said plurality of slots.

22. The plasma processing apparatus according to claim 12, further comprising a retardation plate, disposed on the plane antenna, for adjusting the wavelength of microwaves to be supplied to the plane antenna.
